(19) United States
(12) Patent Application Publication
(10) Pub. No.: US 2002/0076479 A1
(43) Pub. Date: Jun. 20, 2002

(54) Method of monitoring chemical vapor deposition conditions

(75) Inventors: Tzung-Hua Ying, Hualien Hsien (TW); Tang Yu, Hsinchu Hsien (TW); Jumn-Min Fan, Hsinchu Hsien (TW)

Correspondence Address: Daniel R. McClure, THOMAS, KAYDEN, HORSTEMEYER & RISLEY, L.L.P., Suite 1750, 100 Galleria Parkway N.W., Atlanta, GA, 30339, US

(73) Assignee: United Microelectronics Corp., Hsinchu (TW)

(21) Appl. No.: 09/752,035

(22) Filed: Dec. 29, 2000

(30) Foreign Application Priority Data
Dec. 18, 2000 (TW) 89127060

(51) Int. Cl. C23C 16/00

(52) U.S. Cl. 427/8; 427/255.394; 427/255.27

(57) ABSTRACT

A method of monitoring the conditions during chemical vapor deposition. First, a first substrate is provided. A first oxide layer is formed over the first substrate and then a first silicon nitride layer is deposited over the first oxide layer under a set of depositing conditions. The first silicon nitride layer is removed so that the remaining first oxide layer can serve as a first measuring oxide layer. The interface trap density of the first measuring oxide layer is measured to obtain a first interface trap density. A second substrate is provided. A second oxide layer is formed over the second substrate. After setting the depositing conditions identical to the set of depositing conditions for depositing the first silicon nitride layer over the first substrate, a second silicon nitride layer is deposited over the second oxide layer. The second silicon nitride layer is performed under an actual set of depositing conditions. The second silicon nitride layer is removed so that the remaining second oxide layer can serve as a second measuring oxide layer. The interface trap density of the second measuring oxide layer is measured to obtain a second interface trap density. By comparing the second interface trap density with the first interface trap density, differences between the actual depositing conditions and the set depositing conditions are obtained.

### CROSS-REFERENCE TO RELATED APPLICATION

This application claims the priority benefit of Taiwan application serial no. 89127060, filed Dec. 18, 2000.

### BACKGROUND OF THE INVENTION

1. Field of Invention

The present invention relates to a method of monitoring the various conditions during chemical vapor deposition. More particularly, the present invention relates to a method of monitoring the conditions during chemical vapor deposition using interface trap density (ITD).

2. Description of Related Art

In semiconductor fabrication, various thin films such as dielectric layers and insulating layers are formed by chemical vapor deposition. At present, items monitored during chemical vapor deposition include thickness, refractive index, stress, etching rate and so on.

However, when there is a shift in depositing conditions such as deposition temperature, pressure and flow rate of gaseous reactants, the aforementioned list of monitored items cannot accurately reflect any true abnormality. Hence, if some hardware problem occurs during vapor deposition, the conventional system can hardly detect such changes in depositing conditions as pressure and gaseous reactant flow rate variation. Ultimately, a large batch of finished product may have to be scrapped leading to a drop in yield and lost for the particular manufacturer.

### SUMMARY OF THE INVENTION

Accordingly, one object of the present invention is to provide a method of monitoring the conditions during chemical vapor deposition. The method includes the following steps. First, a first substrate is provided. A first oxide layer is formed over the first substrate and then a first silicon nitride layer is deposited over the first oxide layer under a set of depositing conditions. The first silicon nitride layer is removed so that the remaining first oxide layer can serve as a first measuring oxide layer. The interface trap density of the first measuring oxide layer is measured to obtain a first interface trap density. A second substrate is provided. A second oxide layer is formed over the second substrate. After setting the depositing conditions identical to the set of depositing conditions for depositing the first silicon nitride layer over the first substrate, a second silicon nitride layer is deposited over the second oxide layer. The second silicon nitride layer is performed under an actual set of depositing conditions. The second silicon nitride layer is removed so that the remaining second oxide layer can serve as a second measuring oxide layer. The interface trap density of the second measuring oxide layer is measured to obtain a second interface trap density. By comparing the second interface trap density with the first interface trap density, differences between the actual depositing conditions and the set depositing conditions are obtained.

This invention also provides a method of monitoring the quality of a silicon nitride layer formed by chemical vapor deposition. The method includes the following steps. First, a substrate is provided. An oxide layer is formed over the substrate and then a silicon nitride layer is deposited over the oxide layer under a set of depositing conditions. The silicon nitride layer is removed. The interface trap density of the oxide layer is measured. According to the measured interface trap density, relative nitride concentration within the silicon nitride layer corresponding to the interface trap density is looked up from a reference table. The set of depositing conditions in this invention includes temperature, pressure and the flow rates of gaseous reactants.

Since nitride concentration in a silicon nitride layer differs according to the set of depositing conditions, a comparison of the measured interface trap densities may reveal actual nitride concentration with the silicon nitride layer. Ultimately, any drift in the set of depositing conditions such as temperature, pressure and flow rates of various gaseous reactants can be monitored and quality of deposited layer can be maintained. In addition, this invention is capable of obtaining information about the quality of a silicon nitride layer by measuring the interface trap density and comparing with a reference table to find a corresponding nitride concentration. For example, when the interface trap density is high, nitride concentration within the silicon oxide layer is relatively high. Conversely, when the nitride concentration within the silicon nitride layer is low, silicon concentration within the silicon nitride layer is relatively high. If the silicon content within the silicon nitride layer is high, the capacity to resist oxidation will drop. By comparing interface trap densities, relative concentration of nitride between different silicon nitride layers can be found. Hence, information regarding the quality and properties of a particular nitride layer may be obtained.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 3 are schematic cross-sectional views showing the method for forming a measuring silicon oxide layer according to one embodiment of this invention;

FIG. 4 is a flow chart showing the steps for monitoring the quality of a silicon nitride layer during chemical vapor deposition according to this invention; and

FIG. 5 is a chart showing the measured interface trap density under various set of depositing conditions according to this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

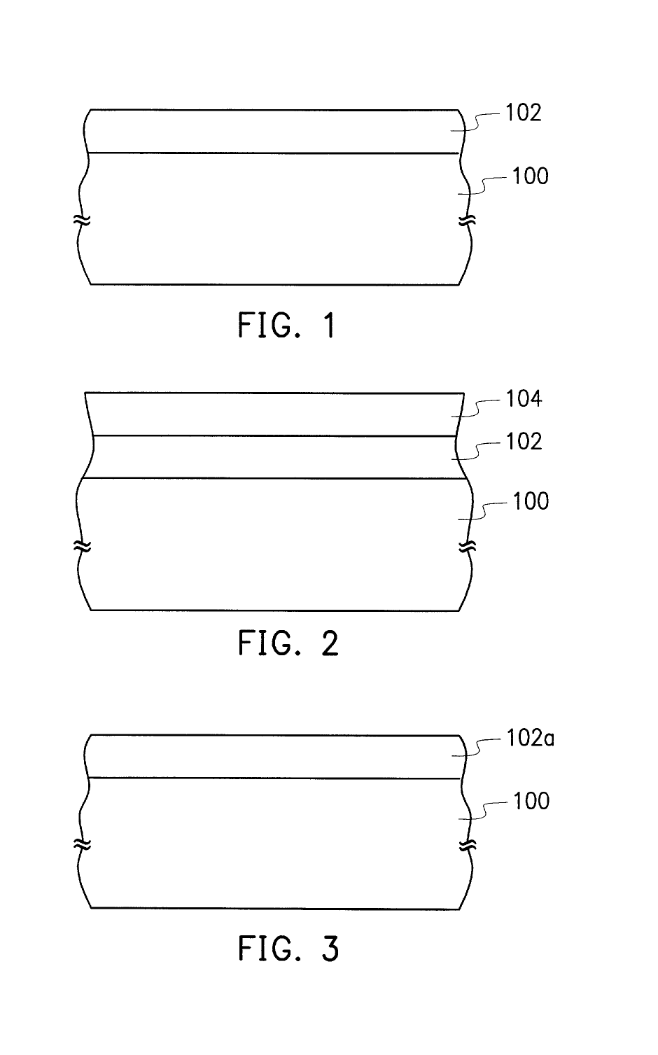

FIGS. 1 through 3 are schematic cross-sectional views showing the method for forming a measuring silicon oxide layer according to one embodiment of this invention.

As shown in FIG. 1, an oxide layer 102 is formed over a substrate 100. The oxide layer 102 is preferably formed by thermal oxidation because a thermally oxidized layer can prevent the accumulation of contaminants in a deposition process. In general, the substrate 100 is a semiconductor substrate such as a silicon substrate. If the substrate 100 is a silicon substrate, the oxide layer 102 is a silicon oxide layer.

As shown in FIG. 2, chemical vapor deposition is conducted to form a silicon nitride layer 104 over the oxide layer 102. The silicon nitride layer 104 is deposited under a set of depositing conditions. The depositing conditions include depositing temperature, depositing pressure and the relative flow rates of various gaseous reactants.

As shown in FIG. 3, the silicon nitride layer 104 is removed. The silicon nitride layer 104 can be removed by hot phosphoric acid (H₃PO₄) solution. After the silicon nitride layer 104 is removed, an oxide layer 102a remains above the substrate 100. The oxide layer 102a can serve as a measuring silicon oxide layer. The interface trap density of the measuring oxide layer 102a is measured. By checking the interface trap density on a reference table, corresponding nitride concentration in the oxide layer 102a can be obtained. The interface trap density is a measure of the number of energy levels per unit area per energy unit having a unit (1/eV.cm²), where eV is electron volt (an energy unit), and cm² is area in centimeter square.

Similar method using the steps depicted in FIGS. 1 through 3 may be used to form another measuring oxide layer over a substrate. The method includes the following steps. First, another substrate having an oxide layer thereon is provided. A silicon nitride layer is deposited over the oxide layer using the same set of depositing conditions as the conditions for depositing the silicon nitride layer 104. When the set of depositing condition contains some deviation, in other words, when the conditions for depositing the silicon nitride layer differs slightly from the set temperature, pressure and gases flow rates, the deviations can be monitored by measuring the interface trap density of the measuring oxide layer after the silicon nitride layer is removed. If the two interface trap density measurements are different, the actual set of depositing conditions including the actual depositing temperature, depositing pressure and gas flow rates is different from the set depositing conditions. Ultimately, any parameters that lead to the change can be found. Since the measuring oxide layer is formed by an identical method as shown in FIGS. 1 to 3, diagrams for illustrating the process are not drawn.

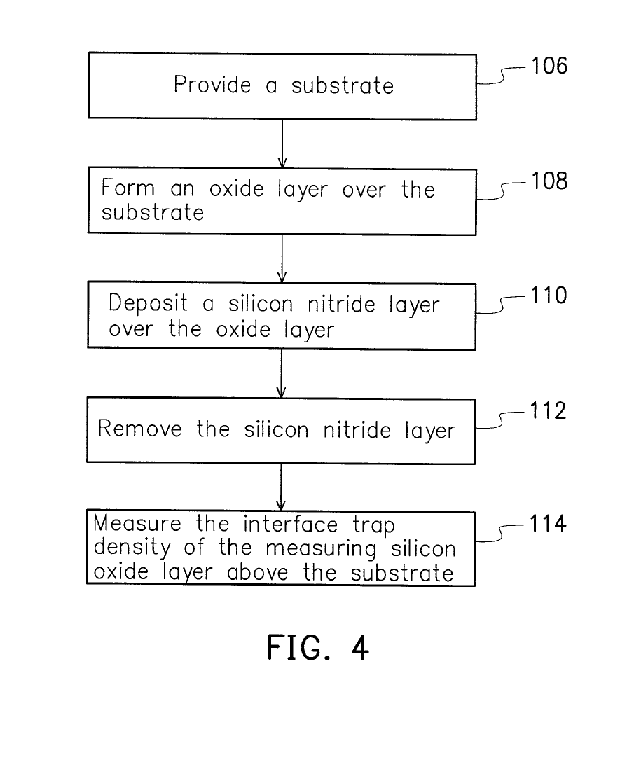

FIG. 4 is a flow chart showing the steps for monitoring the quality of a silicon nitride layer during chemical vapor deposition according to this invention. As shown in FIG. 4, a substrate is provided in step 106. An oxide layer is formed over the substrate in step 108. A silicon nitride layer is formed over the oxide layer by deposition in step 110. The silicon nitride layer is removed in step 112 retaining the oxide layer above the substrate to become a measuring oxide layer. Thereafter, the measuring oxide layer and the substrate is placed inside a monitoring machine to measure the interface trap density of the measuring oxide layer in step 114. Through a reference table that lists out the relationship between interface trap density and nitride concentration, nitride concentration inside the measuring oxide layer can be found. Hence, quality of the silicon nitride layer can be obtained. For example, when the interface trap density is high, nitride concentration within the silicon oxide layer is relatively high. Conversely, when the nitride concentration within the silicon nitride layer is low, silicon concentration within the silicon nitride layer is relatively high. If the silicon content within the silicon nitride layer is high, the capacity to resist oxidation will drop. By comparing interface trap densities, relative concentration of nitride between different silicon nitride layers can be found. Hence, information regarding the quality and properties of a particular nitride layer may be obtained.

In addition, the invention can compare the interface trap density of different measuring oxide layer. By gauging nitride concentration within the measuring oxide layer, any drift in the set of depositing conditions while silicon nitride is being deposited can be monitored. For example, after forming a silicon nitride layer over the silicon oxide layer, nitrogen atoms may diffuse into the silicon oxide layer. Hence, a silicon-rich layer is formed at the interface between the silicon nitride layer and the silicon oxide layer. The quantity of nitrogen atoms diffuse to the silicon oxide layer is subjected to the set of depositing conditions including temperature, pressure and gas flow rates. On the contrary, if the silicon nitride layer is formed over the silicon substrate, nitrogen atoms will remain on the silicon substrate surface waiting to react with the silicon atoms dissociated from the reactive gas SiH₂Cl₂. Hence, by forming a silicon nitride layer over the oxide layer and measuring the interface trap density of the oxide layer after the silicon nitride layer is removed, drift in the depositing conditions can be monitored.

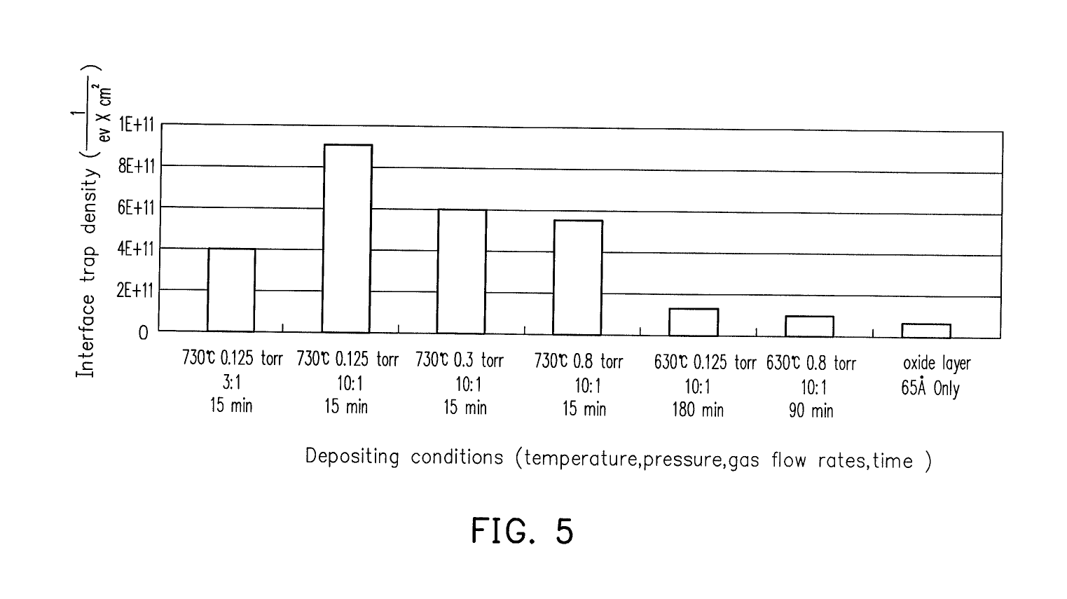

FIG. 5 is a chart showing the measured interface trap density under various set of depositing conditions according to this invention. According to the chart in FIG. 5, the effects of temperature, pressure and relative gas flow rates on nitride content within the oxide layer are as follows:

1. The higher the temperature, the higher will be the interface trap density and the nitride concentration within the oxide layer. This is because the nitrogen atoms are increasingly mobile as the temperature is increased causing more nitrogen atoms can diffuse to the oxide layer.

2. The higher the pressure, the lower will be the interface trap density and the nitride concentration within the oxide layer. This is because high pressure will increase the collision rate between nitrogen atoms and silicon atoms within the respective compounds NH₃ and SiH₂Cl₂ under the same temperature and reactant flow rates. Consequently, probability of nitrogen atoms diffusing to the oxide layer is lowered.

3. If the gaseous reactants are NH₃ and SiH₂Cl₂, the lower the gas flow rates, the lower will be the interface trap density and the lower will be the nitride concentration within the oxide layer. This is because a lower gas flow rate at the same temperature and pressure increases the probability of collisions between the nitrogen atoms and the silicon atoms of the gaseous reactants. Ultimately, the nitrogen atoms will have fewer chances of diffusing into the oxide layer.

In this invention, a comparison of the measured interface trap densities may reveal actual nitride concentration with the silicon nitride layer. Since any drift in the set of depositing conditions such as temperature, pressure and flow rates of various gaseous reactants can be monitored, quality of the deposited layer can be maintained. In addition, this invention is capable of obtaining information about the quality of a silicon nitride layer by measuring the interface trap density and comparing with a reference table to find a corresponding nitride concentration. For example, when the interface trap density is high, nitride concentration within the silicon oxide layer is also high. Conversely, when the nitride concentration within the silicon nitride layer is low, silicon concentration within the silicon nitride layer is high. If the silicon content within the silicon nitride layer is high, the capacity to resist oxidation will drop. By comparing interface trap densities, relative concentration of nitride between different silicon nitride layers can be found. Hence, information regarding the quality and properties of a particular nitride layer may be obtained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of monitoring the conditions during chemical vapor deposition, comprising the steps of:
providing a first substrate;
forming a first oxide layer over the first substrate;
depositing a first silicon nitride layer over the oxide layer under a first set of depositing conditions;
removing the first silicon nitride layer but retaining the first oxide layer above the first substrate as a first measuring oxide layer;
measuring the interface trap density of the first measuring oxide layer to obtain a first interface trap density and using the first interface trap density as a reference value;
providing a second substrate; forming a second oxide layer over the second substrate;
depositing a second silicon nitride layer over the second oxide layer using a set of depositing conditions identical to the first set of depositing conditions for depositing the first silicon nitride layer, wherein deposition of the second silicon nitride layer is carried out under an actual set of depositing condition;
removing the second silicon nitride layer but retaining the second oxide layer over the second substrate serving as a second measuring oxide layer; and
measuring the interface trap density of the second measuring oxide layer to obtain a second interface trap density and comparing the second interface trap density with the first interface trap density to obtain the difference between the first set of depositing conditions and the second set of depositing conditions.

2. The method of claim 1, wherein the first substrate includes a silicon substrate.

3. The method of claim 1, wherein the step of forming the first oxide layer over the first substrate includes thermal oxidation.

4. The method of claim 1, wherein the first oxide layer includes a silicon oxide layer.

5. The method of claim 1, wherein the depositing condition includes depositing temperature.

6. The method of claim 1, wherein the depositing condition includes depositing pressure.

7. The method of claim 1, wherein the depositing condition includes the gas flow rates of gaseous reactants.

8. The method of claim 1, wherein the step of removing the first silicon nitride layer includes using hot phosphoric acid solution.

9. The method of claim 1, wherein the second substrate includes a silicon substrate.

10. The method of claim 1, wherein the step of forming the second oxide layer over the second substrate includes thermal oxidation.

11. The method of claim 1, wherein the second oxide layer includes a silicon oxide layer.

12. The method of claim 1, wherein the step of removing the second silicon nitride layer includes using hot phosphoric acid solution.

13. The method of claim 1, wherein the first depositing conditions and the actual depositing conditions are identical when the first interface trap density and the second interface trap density are identical.

14. The method of claim 1, wherein the set of actual depositing conditions deviates from the first set of depositing conditions when the first interface trap density and the second interface trap density are different.

15. A method of monitoring the quality of a silicon nitride layer during chemical vapor deposition, comprising the steps of:
providing a substrate;
forming an oxide layer over the substrate;
depositing a silicon nitride layer over the oxide layer under a set of depositing conditions;
removing the silicon nitride layer but retaining the oxide layer above the substrate serving as a measuring oxide layer; and
measuring the interface trap density of the measuring oxide layer and finding nitride concentration within the measuring oxide layer by referring to a reference table that lists out the correspondence relationship between nitride concentration and interface trap density.

16. The method of claim 15, wherein the first substrate includes a silicon substrate.

17. The method of claim 15, wherein the first oxide layer includes a silicon oxide layer formed by thermal oxidation.

18. The method of claim 15, wherein the depositing condition includes depositing temperature.

19. The method of claim 15, wherein the depositing condition includes depositing pressure.

20. The method of claim 15, wherein the depositing condition includes flow rates of gaseous reactants.
